(19) United States
(12) Patent Application Publication
(10) Pub. No.: US 2016/0334785 A1
(43) Pub. Date: Nov. 17, 2016

(54) CONTROL UNIT ADAPTED TO ACCOMMODATE DRONE

(71) Applicant: Robert Morrison, Walworth, NY (US)

(72) Inventor: Robert Morrison, Walworth, NY (US)

(21) Appl. No.: 14/710,682

(22) Filed: May 13, 2015

(51) Int. Cl. G05D 1/00; B64C 39/02; H05K 5/03; H05K 5/00; H05K 5/02

(52) U.S. Cl. CPC G05D 1/0016; H05K 5/0017; H05K 5/0226; H05K 5/03; B64C 39/024; B64C 2201/146

(57) ABSTRACT

A control unit for a drone, said control unit comprising a protective case, a controller capable of remote operation of the drone and a space configured to receive the drone within said protective case for storage, wherein the drone is contained in its entirety within said protective case.

### BACKGROUND OF THE INVENTION

1. The Field of the Invention

The present invention is directed generally to a control unit of a drone. More specifically, the present invention is directed to a control unit that can house a drone.

2. Background Art

Although the size of most hobby-grade drones is considered small, they are incapable of being stowed within their respective control units. A control unit of a hobby-grade drone typically comes in a non-rectangular shape that is considered aesthetically appealing to some but otherwise serving no practical purposes. Storing a drone separately from its control unit causes the need to transport the drone separately from the control unit. Tremendous care must be taken to ensure that a drone is associated with a particular control unit or the user of such drone must risk losing either the drone or the control unit or inadvertently separating the drone from its control unit such that the drone is no longer operable. There are drones that attach to a portion of a control unit, however the drone is still unprotected despite being secured to the control unit. A user can still run the risk of getting the drone separated from the control unit. Further, such design is non-compact, with various irregularly shaped parts of the control unit-drone combination presenting a barrier for them to be tucked away nicely in a confined space, e.g., a ubiquitously available shirt or pants pocket, etc.

Thus, there is a need for a drone that is capable of being securely stored and transported with the rest of the drone system and its control unit.

### SUMMARY OF THE INVENTION

In accordance with the present invention, there is provided a control unit for a drone, the control unit comprising:
(a) a protective case;
(b) a controller capable of remote operation of the drone; and
(c) a space configured to receive the drone within the protective case for storage,
wherein the drone is contained in its entirety within the protective case.

In one embodiment, a pair of joysticks that is functionally connected to the controller is further provided. The drone storage space is located between the pair of joysticks within the protective case. In one embodiment, each joystick includes a detachable handle. The control unit further includes posts configured for storing handles of the joysticks, wherein the posts are disposed within the protective case.

In one embodiment, the protective case of the control unit is substantially rectangular and further includes a front cover, a rear cover, a length, a width and a height, and the control unit further includes at least one control button disposed on the rear cover of the protective case wherein the at least one control button is functionally connected to the controller. In one embodiment, the length of the protective case measures up to about 108 mm, the width measures up to about 86 mm and the height measures up to about 24 mm. In one embodiment, the controller includes a volume of no more than about 223 cubic cm.

In one embodiment, at least a portion of the protective case is transparent and is disposed on the front cover.

In one embodiment, the control unit further includes a charging device pivotally attached to a portion of the interior of the protective case to assume an erected position or a retracted position. The charging device is adapted to charge a battery within the drone when the charging device is connected to the battery. The drone is configured to be attachable to or removable from the charging plug while it is disposed in the erected position and the drone is configured to be seated in the retracted position.

In one embodiment, the control unit further includes at least one control button having a control button post, wherein the at least one control button is disposed on one of the two covers and configured to trigger at least one control button disposed on the other one of the two covers with the control button post.

In one embodiment, the protective case of the control unit includes a front cover, a rear cover and an adhesive tape hingedly connecting the front cover and the rear cover.

An object of the present invention is to provide a drone securing mechanism which fully protects the drone from damage or being separated from its control unit due to inadvertent snagging of the drone from the control unit to which it may be attached.

An object of the present invention is to provide a drone securing mechanism where the drone can be stowed in its entirety within a protective case.

An object of the present invention is to provide a drone securing mechanism where the drone can be stowed in its entirety in a protective case capable of being stored in ubiquitous shirt or pants pocket.

Whereas there may be many embodiments of the present invention, each embodiment may meet one or more of the foregoing recited objects in any combination. It is not intended that each embodiment will necessarily meet each objective. Thus, having broadly outlined the more important features of the present invention in order that the detailed description thereof may be better understood, and that the present contribution to the art may be better appreciated, there are, of course, additional features of the present invention that will be described herein and will form a part of the subject matter of this specification.

### BRIEF DESCRIPTION OF THE DRAWINGS

In order that the manner in which the above-recited and other advantages and objects of the invention are obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 is a front perspective partially transparent view of one embodiment of the present control unit.

FIG. 2 is a front perspective view of one embodiment of the present control unit with a protective case disposed in its open configuration, depicting the interior arrangement of components within the protective case without a drone.

FIG. 3 is a front perspective view of one embodiment of the present control unit with a protective case disposed in its open configuration, depicting the interior arrangement of components within the protective case with a drone seated in the rear cover.

FIG. 4 is a side view of one embodiment of the present control unit with the joystick handles installed.

FIG. 5 is a side view of one embodiment of the present control unit with the joystick handles removed.

FIG. 6 is a rear view of one embodiment of the present control unit.

FIG. 7 is a top view of one embodiment of the present control unit.

FIG. 8 is a top view of one embodiment of the present control unit with the protective case opened to reveal components within the protective case.

### PARTS LIST

2—control unit

4—drone

6—controller

8—joystick

10—space within which drone is stowed

12—charging arm

14—charging plug

16—joint

18—handle

20—socket for receiving handle

22—post for storing handle

24—battery holder

26—battery

28—control button

30—front cover

32—rear cover

34—viewing window

36—opening

38—control button post

40—joystick socket

42—charging socket

44—button disposed on front cover

46—button disposed on rear cover

48—adhesive tape

50—height of protective case

52—width of protective case

54—length of protective case

56—protective case

58—side wall

### PARTICULAR ADVANTAGES OF THE INVENTION

The present control unit is adapted to store a drone, thereby ensuring that the drone is transported together with the control unit and eliminating the possibility that the drone becomes separated from its control unit. Prior art control units may come with docking units outside of the control units to which drones are attached. However, securing the drones outside of the control units still leave the drones vulnerable to snagging and tangling risks which can separate them from their respective control units.

### DETAILED DESCRIPTION OF A PREFERRED EMBODIMENT

The term “about” is used herein to mean approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower).

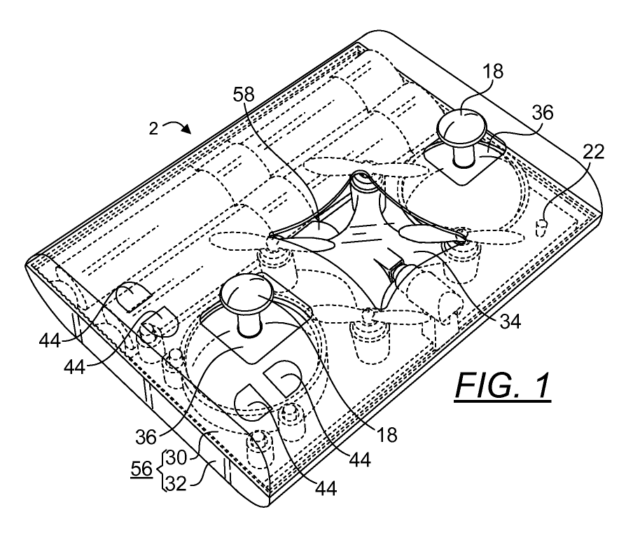

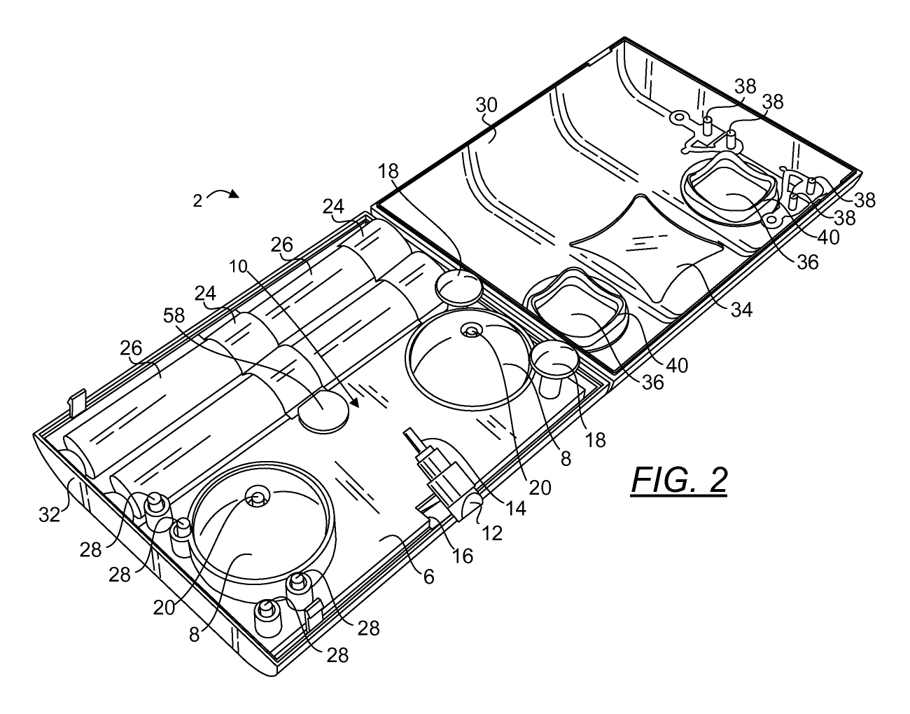

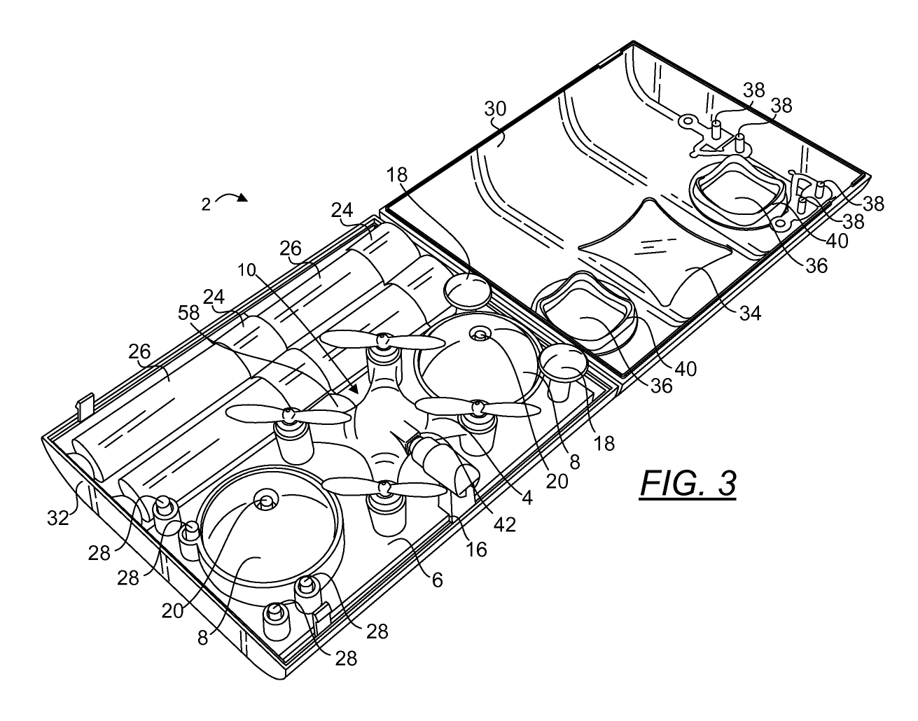

FIG. 1 is a front perspective partially transparent view of one embodiment of the present control unit 2. FIG. 2 is a front perspective view of one embodiment of the present control unit 2 with a protective case 56 disposed in its open configuration, depicting the interior arrangement of components within the protective case 56 without a drone 4. FIG. 3 is a front perspective view of one embodiment of the present control unit 2 with a protective case 56 disposed in its open configuration, depicting the interior arrangement of components within the protective case 56 with a drone 4 seated within the rear cover 32.

The protective case 56 of the control unit 2 is substantially rectangular and further includes a front cover 30 and a rear cover 32 which are configured to cooperate to form the protective case 56. Various techniques, e.g. by using tongue-and-grooves, etc., are available to transform the covers 30, 32 into removably attachable covers to ensure that the protective case 56 is not inadvertently opened but yet easily opened when the interior of the protective case 56 is intended to be accessed. The corners of the front and rear covers 30, 32 are preferably rounded such that the protective case 56 may be more easily inserted or retrieved from a shirt or pants pocket. In this embodiment, the drone 4 is a quadcopter. Examples of other drones 4 include, but are not limited to, a helicopter, a fixed wing plane, and a multi-rotor aircraft. In place of a drone 4, a ground vehicle, a boat and any machines functionally controlled by the control unit 2 may be contained in the protective case 56. Disclosed herein is a control unit 2 for a drone 4. The control unit 2 includes a protective case 56, a controller 6 capable of remote operation of the drone 4 and a space 10 configured to receive the drone 4 within the protective case 56 for storage. It shall be noted from FIG. 1 that the drone 4 is contained in its entirety within the protective case 56. Attempts have previously been made by others to attach a drone or other machines to their respective controllers to result in a combination of a machine and its control unit. In such attempts however, each machine is disposed outside of its control unit. In contrast, in the present invention, a machine is disposed within its control unit in its entirety.

In one embodiment, a pair of joysticks 8 having detachable handles 18 are further provided. Each joystick 8 is functionally connected to the controller 6. In the io embodiment shown in FIGS. 1-3, the space 10 is located between the pair of joysticks 8 within the protective case 56. In one example, one of the joysticks 8 is used to control the throttle of the drone 4. The other one of the joysticks 8 is used to control the travel direction and attitude of drone 4. In one embodiment, each joystick 8 includes a detachable handle 18. The control unit 2 further includes posts 22 configured for storing handles 18 of joysticks 8. Each post 22 is disposed within the protective case 56. In one embodiment, the control unit 2 further includes a charging device pivotally attached to a portion of the interior of the protective case 56 to assume an erected position or a retracted position.

The charging device is essentially an arm 12 having a charging plug 14 at its tip. The charging device is adapted to charge a battery within the drone 4 when the charging device is connected to the battery. In stowing the drone 4 in the protective case 56, after use, the protective case 56 is first opened such that the drone 4 placed within the front cover 30 and rear cover 32 is accessible. This is followed by tilting or erecting the charging arm 12 by rotating the arm 12 about a joint 16 such that the charging plug 14 points upwardly at an incline to a flat portion of the rear cover 32 to anticipate the docking of drone 4. The charging plug 14 is then inserted in the charging socket 42 of the drone 4. The arm 12 is then rotated downwardly such that the drone is now seated within the space 10 allocated in the control unit 2. While seated, the drone 4 is incapable of lateral movement as it is bounded by the side wall 58, as well as up-down movements as it is limited by the charging device and the front cover 30. The handles 18 may be pulled from their respective sockets 20 and seated on posts 22. The protective case 56 is then closed such that the components within the front cover 30 and rear cover 32 are protected along with the handles 18 and the drone 4. While disposed in the protective case 56, the battery of the drone 4 is being charged while it is being safely stored and/or transported.

In retrieving the drone 4, the protective case 56 is opened and the charging arm 12 is disposed in its erected position, enabling the drone 4 to be separated from the plug 14. Also shown in FIGS. 1-3 are batteries 26 held together by battery holders 24. Such batteries 26 are used to power the control unit 2 and charge the battery of the drone 4. Also shown in FIGS. 2-3 are openings 36 disposed on the front cover 30 which allow the insertion and removal of the handles 18 and access to the joysticks 8 and joystick sockets 40 which are essentially boots which help minimize the gaps between the front cover 30 and the joysticks 8 to reduce intrusions of dusts and other contaminants.

In one embodiment, at least a portion of the protective case 56 is transparent and is disposed on the front cover 30. In one embodiment, a viewing window 34 is centrally disposed over space 10 to allow a user to quickly ascertain whether a drone 4 is already seated in the space 10 when the protective case 56 is closed.

In one embodiment, the control unit 2 further includes a plurality of control buttons 44 disposed on the front cover 30, each control button 44 having a control button post 38. The depression of a button 44 disposed on the front cover 30 is transferred to a control button 28 disposed on the rear cover 32. Therefore, by placing a control button disposed on a first cover to trigger a control button 28 disposed on the interior of a second cover, the control button can be advantageously placed such that it is accessible both from the outside of a first cover and yet favorably located in the interior of a second cover opposingly disposed from the first cover.

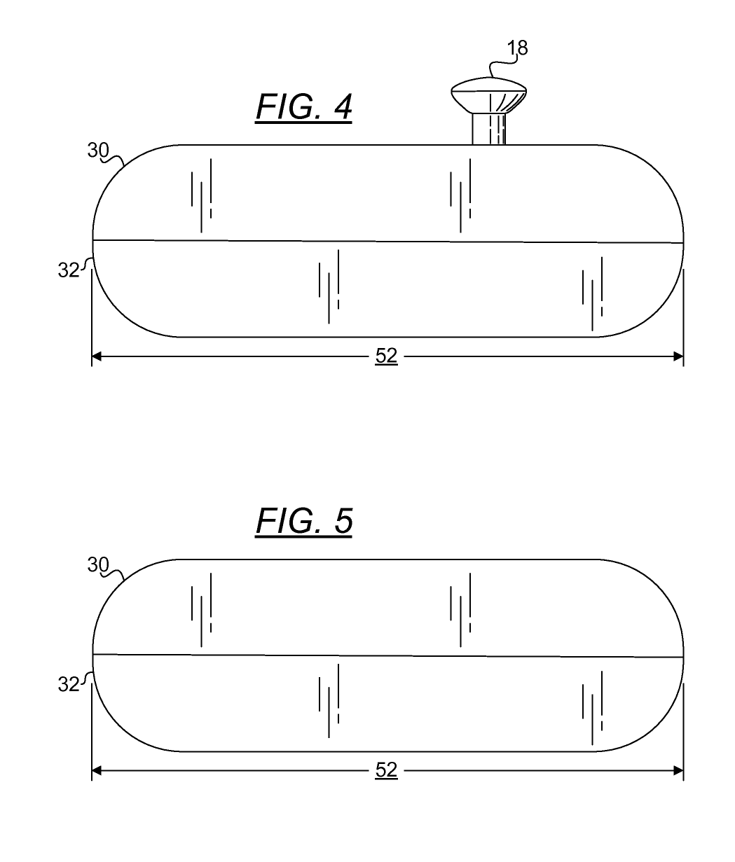

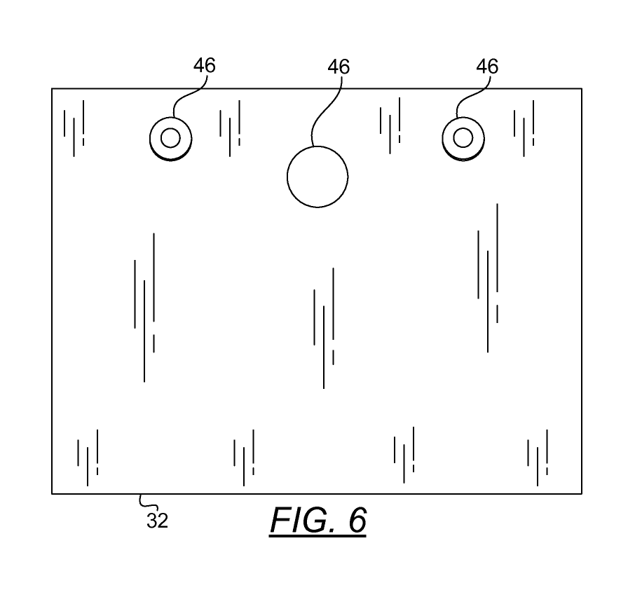

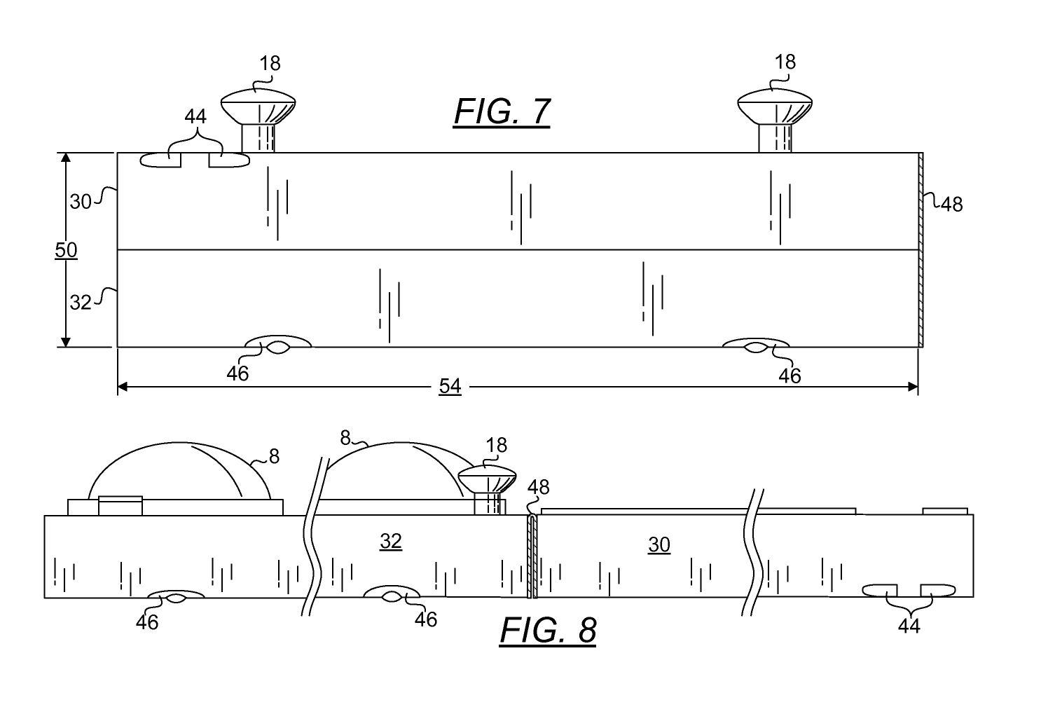

FIG. 4 is a side view of one embodiment of the present control unit 2 with the joystick handles 18 installed. FIG. 5 is a side view of one embodiment of the present control unit 2 with the joystick handles 18 removed. FIG. 6 is a rear view of one embodiment of the present control unit 2. FIG. 7 is a top view of one embodiment of the present control unit 2. Referring to FIGS. 4, 5 and 7, the protective case 56 further includes a length 54, a width 52 and a height 50. In one embodiment, the length 54 of the protective case 56 measures up to about 108 mm, the width 52 measures up to about 86 mm and the height 50 measures up to about 24 mm. In one embodiment, the control unit 2 has a volume of no more than about 223 cubic cm to facilitate stowage and transport of the control unit 2.

In the embodiment shown in FIG. 6, the control unit 2 further includes several control buttons 46 disposed on the rear cover 32 of the protective case 56 where the control buttons 46 are functionally connected to the controller 6. In use, a control unit 2 is clutched with two hands, with each thumb of a hand controlling one or more functions of the drone 4 by adjusting the joystick position and the other fingers placed at the rear cover 32 to cooperatingly work with the thumb to control one or more functions of the drone 4 via control buttons 46 disposed on the rear cover 32. Applicant discovered that when placed within the reach of an index finger or middle finger during the normal use of the control unit 2, only small movements of a hand of the user is required to press a control button 46 disposed on the rear cover 32, thereby rendering such movement effortless, swift and responsive. Control buttons 44, 46 may be used, e.g., for executing trick modes, making adjustments to motor power, etc.

FIG. 8 is a top view of one embodiment of the present control unit 2 with the protective case 56 opened to reveal components within the protective case 56. It shall be noted that, in this embodiment, an adhesive tape 48 is disposed on one side of the protective case 56, hingedly connecting the front cover 30 and the rear cover 32. Other means for hingedly connecting the two covers 30, 32 may also be used, e.g., by providing one or more hinges to connect one side of each cover 30, 32. In yet another embodiment, no hinges are provided. The front and rear covers 30, 32 are simply removably attached with techniques disclosed elsewhere herein.

The detailed description refers to the accompanying drawings that show, by way of illustration, specific aspects and embodiments in which the present disclosed embodiments may be practiced. These embodiments are described in sufficient detail to enable those skilled in the art to practice aspects of the present invention. Other embodiments may be utilized, and changes may be made without departing from the scope of the disclosed embodiments. The various embodiments can be combined with one or more other embodiments to form new embodiments. The detailed description is, therefore, not to be taken in a limiting sense, and the scope of the present invention is defined only by the appended claims, with the full scope of equivalents to which they may be entitled. It will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present disclosed embodiments includes any other applications in which embodiments of the above structures and fabrication methods are used. The scope of the embodiments should be determined with reference to the appended claims, along with the full scope of equivalents to which such claims are entitled.

I claim:

1. A control unit 2 for a drone, said control unit comprising:
(a) a protective case 56;
(b) a controller 6 capable of remote operation of the drone; and
(c) a space 10 configured to receive the drone within said protective case 56 for storage,
wherein the drone is contained in its entirety within said protective case.

2. The control unit 2 of claim 1, further comprising a pair of joysticks 8 functionally connected to said controller 6, wherein said space 10 is located between said pair of joysticks 8 within said protective case 56.

3. The control unit of claim 1, wherein said protective case 56 is substantially rectangular and further comprises a rear cover 32 and said control unit 6 further comprises at least one control button 46 disposed on said rear cover 32 of said protective case 56 and said at least one control button 46 is functionally connected to said controller 6.

4. The control unit 2 of claim 1, further comprising a length 54, a width 52 and a height 50, wherein said length 54 measures up to about 108 mm, said width 52 measures up to about 86 mm and said height 50 measures up to about 24 mm.

5. The control unit 2 of claim 1, wherein said control unit 2 includes a volume of no more than about 223 cubic cm.

6. The control unit 2 of claim 1, further comprising at least one joystick 8 having a detachable handle 18.

7. The control unit 2 of claim 1, further comprising at least one post 22 configured for storing at least one handle 18 of a joystick 8, wherein said post 22 is disposed within said protective case 56.

8. The control unit 2 of claim 1, wherein at least a portion of said protective case 56 is transparent.

9. The control unit 2 of claim 1, further comprising a front cover 30, wherein at least a portion of said protective case 56 is transparent and is disposed on said front cover 30.

10. The control unit 2 of claim 1, further comprising a charging device pivotally attached to a portion of the interior of said protective case 56 to assume one of an erected position and a retracted position, wherein said charging device is adapted to charge a battery within the drone when said charging device is connected to the battery, and wherein the drone is configured to be removable in said erected position and the drone is configured to be seated in said retracted position.

11. The control unit 2 of claim 1, further comprising at least one control button 44 having a control button post 38, wherein said protective case 56 comprises two covers 30, 32 configured to cooperate to form said protective case 56 and said at least one control button 44 is disposed on one of said two covers 30, 32 and configured to trigger at least one control button 28 disposed on the other one of said two covers with said control button post 38.

12. The control unit 2 of claim 1, wherein said protective case 56 comprises a front cover 30, a rear cover 32 and an adhesive tape 48 hingedly connecting said front cover 30 and said rear cover 32.

13. A control unit 2 for a drone, said control unit comprising:
(a) a protective case 56;
(b) a controller 6 capable of remote operation of the drone;
(c) a space 10 configured to receive the drone within said protective case 56 for storage; and
(d) a pair of joysticks 8 functionally connected to said controller 6,
wherein the drone is contained in its entirety within said protective case.

14. The control unit of claim 13, wherein said protective case 56 is substantially rectangular and further comprises a rear cover 32 and said control unit 6 further comprises at least one control button 46 disposed on said rear cover 32 of said protective case 56 and said at least one control button 46 is functionally connected to said controller.

15. The control unit 2 of claim 13, wherein at least one joystick 8 of said pair of joysticks 8 comprises a detachable handle 18.

16. The control unit 2 of claim 13, further comprising at least one post 22 configured for storing at least one joystick, wherein said post 22 is disposed within said protective case 56.

17. The control unit 2 of claim 13, wherein at least a portion of said protective case 56 is transparent.

18. The control unit 2 of claim 13, further comprising a charging device pivotally attached to a portion of the interior of said protective case 56 to assume one of an erected position and a retracted position, wherein said charging device is adapted to charge a battery within the drone when said charging device is connected to the battery, the drone is configured to be removable in said erected position and the drone is configured to be seated in said retracted position.

19. The control unit 2 of claim 13, further comprising at least one control button 44 having a control button post 38, wherein said protective case 56 comprises two covers 30, 32 configured to cooperate to form said protective case 56 and said at least one control button 44 is disposed on one of said two covers 30, 32 and configured to trigger at least one control button 28 disposed on the other one of said two covers with said control button post 38.

20. The control unit 2 of claim 13, wherein said protective case 56 comprises a front cover 30, a rear cover 32 and an adhesive tape 48 hingedly connecting said front cover 30 and said rear cover 32.
